(19) United States
(12) Patent Application Publication
(10) Pub. No.: US 2016/0013286 A1
(43) Pub. Date: Jan. 14, 2016

(54) SCHOTTKY BARRIER DIODE FORMED WITH NITRIDE SEMICONDUCTOR SUBSTRATE

(71) Applicant: TOYOTA JIDOSHA KABUSHIKI KAISHA, Toyota-shi (JP)

(72) Inventors: Hidemoto TOMITA, Toyota-shi (JP); Masakazu KANECHIKA, Nagakute-shi (JP); Hiroyuki UEDA, Nagakute-shi (JP); Koichi NISHIKAWA, Nagakute-shi (JP)

(21) Appl. No.: 14/721,291

(22) Filed: May 26, 2015

(30) Foreign Application Priority Data
Jul. 10, 2014 (JP) 2014-141916

(51) Int. Cl. H01L 29/47; H01L 29/872

(52) U.S. Cl. CPC H01L 29/475; H01L 29/872

(57) ABSTRACT

An SBD is obtained by forming, on a front surface of a substrate in which a first nitride semiconductor layer and a second nitride semiconductor layer are laminated, an anode electrode configured to make Schottky contact and a cathode electrode configured to make Ohmic contact. The anode electrode is made to have a mixture of a portion that is in direct contact with the second nitride semiconductor layer and a portion that is in contact with the second nitride semiconductor layer via a fourth nitride semiconductor layer and a third nitride semiconductor layer. Using a p-type nitride semiconductor as the fourth layer makes it possible to suppress the leakage current. Using, as the third layer, a nitride semiconductor that is wider in band gap than the second nitride semiconductor layer makes it possible to keep down the lowest value of forward voltage at which a forward current flows.

### CROSS-REFERENCE TO RELATED APPLICATION

This application claims priority to Japanese Patent Application No. 2014-141916 filed on Jul. 10, 2014 the contents of which are hereby incorporated by reference into the present application.

### TECHNICAL FIELD

The present specification discloses a technology for improving the characteristics of a Schottky barrier diode (which is herein referred to as “SBD”) formed with use of a substrate of laminated nitride semiconductor layers.

### DESCRIPTION OF RELATED ART

There has been a known technology for obtaining an SBD by forming an anode electrode and a cathode electrode on a front surface of a nitride semiconductor substrate. There has also been a proposed technology for improving the characteristics of such an SBD.

A structure has been disclosed in which a diode is made lower in forward voltage drop with use of a hetero junction between nitride semiconductor layers (see IEEE, ELECTRON DEVICE LETTERS, Vol. 34, No. 8, AUGUST, 2013). As shown in FIG. 4, when a narrow-band-gap nitride semiconductor layer 6 and a wide-band-gap nitride semiconductor layer 8 are laminated to form a hetero-junction interface, a two-dimensional electron gas spreads along the hetero-junction interface. When an electrode 20 is formed by a material that makes Ohmic contact with the nitride semiconductor layer 8 and an electrode 22 is formed by a material that makes Schottky contact with the nitride semiconductor layer 8, the electrode 20 serves as a cathode electrode and the electrode 22 serves as an anode electrode, so that an SBD is obtained. Since this SBD uses a two-dimensional electron gas that is formed in the nitride semiconductor 6, which is high in electron mobility, this SBD is kept low in forward voltage drop. It should be noted that the reference number 2 refers to a substrate, that the reference number 4 refers to a buffer layer, and that the reference number 28 refers to a passivation film.

SBD has a tendency that a leakage current (backward current) easily flows through the SBD, and that breakdown voltage of the SBD easily becomes insufficient. A technology has been disclosed in which a leakage current is suppressed and a higher breakdown voltage is achieved with use of a p-type nitride semiconductor region (see Maikuroha Denryoku Seiryûyô GaN Shottokî Daiôdo no Kôtaiatsuka no Kenkyu [A Research for Achieving a Higher Breakdown Voltage of a GaN Schottky Diode for Microwave Power Rectification], Sawada, G., March 2009, Tokushima University Master's Thesis). In this technology, as shown in FIG. 5, an n⁻-type GaN layer 8a is formed on an n⁺-type GaN layer 6a, and an anode electrode 22 is formed on the n-type GaN layer 8a by a material that makes Schottky contact with the n⁻-type GaN layer 8a. In the structure of FIG. 5, the n-type GaN layer 8a and the n⁺-type GaN layer 6a are equal in band gap to each other, and the forward voltage drop is not kept down by generating a two-dimensional electron gas along the hetero-junction interface. In this technology, a p-type GaN region 32 is provided in a part of the area where the anode electrode 22 is formed. The partial provision of the p-type GaN region 32 allows a depletion layer to extend from the p-type GaN region 32 into the n⁻-type GaN layer 8a when a backward voltage is applied to the SBD, and the leakage current is suppressed by the depletion layer, the concentration of electric fields is relaxed and a higher breakdown voltage is achieved. It should be noted that the reference number 2 refers to a substrate, the reference number 4 refers to a buffer layer, the reference number 20 refers to a cathode electrode, and the reference numbers 30 refers to SiO₂ film. When the SBD of FIG. 5 is seen in planer view, the anode electrode 22 has a circular shape, the p-type GaN region 32 has a ring shape that extends along an outer periphery of the anode electrode 22, and the cathode electrode 20 surrounds the anode electrode 22.

### BRIEF SUMMARY OF INVENTION

A combination of the technology shown in FIG. 4, in which a hetero junction is used, and the technology shown in FIG. 5, in which a p-type nitride semiconductor region is used, achieves an SBD which is low in forward voltage drop, in which leakage current is suppressed, and which is high in breakdown voltage. However, this combined technology is left with such a problem that the lowest value of forward voltage at which a forward current flows is high. The present specification discloses a technology for reducing a forward voltage at which a forward current starts to flow.

In an SBD disclosed herein, an anode electrode and a cathode electrode are formed on a front surface of a nitride semiconductor substrate.

The nitride semiconductor substrate includes a laminated structure in which a first nitride semiconductor layer, a second nitride semiconductor layer, a third nitride semiconductor layer, and a fourth nitride semiconductor layer are laminated in this order from a back surface side of the nitride semiconductor substrate to a front surface side of the nitride semiconductor substrate. The first nitride semiconductor layer may be obtained by causing a buffer layer to grow on a substrate and causing the first nitride semiconductor layer to grow on the buffer layer. In this case, the nitride semiconductor substrate includes a laminated structure in which the substrate, the buffer layer, the first nitride semiconductor layer, the second nitride semiconductor layer, the third nitride semiconductor layer, and the fourth nitride semiconductor layer are laminated in this order from a back surface of the nitride semiconductor substrate to the front surface of the nitride semiconductor substrate.

When seen in planar view, the nitride semiconductor substrate has some regions from which the third nitride semiconductor layer and the fourth nitride semiconductor layer have been removed. In the regions from which the third nitride semiconductor layer and the fourth nitride semiconductor layer have been removed, the second nitride semiconductor layer is exposed at the front surface of the nitride semiconductor substrate.

The anode electrode is formed in an area extending over a region where the fourth nitride semiconductor layer does not exist and a region where the fourth nitride semiconductor layer exists. For this reason, in a cross-sectional view of the area where the anode electrode is formed, there is a mixture of a region where there is a laminated structure of the first nitride semiconductor layer, the second nitride semiconductor layer, the third nitride semiconductor layer, the fourth nitride semiconductor layer, and the anode electrode and a region where there is a laminated structure of the first nitride semiconductor layer, the second nitride semiconductor layer, and the anode electrode.

In the foregoing, the first nitride semiconductor layer is narrower in band gap than the second nitride semiconductor layer, and the second nitride semiconductor layer is narrower in band gap than the third nitride semiconductor layer. Further, a conductivity type of each of the first nitride semiconductor layer, the second nitride semiconductor layer, and the third nitride semiconductor layer is not a p type, and a conductivity type of the fourth nitride semiconductor layer is a p type.

In the SBD described above, since the first nitride semiconductor layer and the second nitride semiconductor layer, which are in such a relationship that the first nitride semiconductor layer is narrower in band gap than the second nitride semiconductor layer, are laminated, a two-dimensional electron gas is generated along the junction interface at a boundary between the first nitride semiconductor layer and the second nitride semiconductor layer, so that the diode can be kept low in forward voltage drop.

Further, a depletion layer extends from the p-type fourth nitride semiconductor region into the first nitride semiconductor layer to suppress the leakage current, so that the concentration of electric fields is relaxed and a higher breakdown voltage is achieved.

Furthermore, in the SBD described above, since the band gap of the second nitride semiconductor layer is narrower than the band gap of the third nitride semiconductor layer, the density of electrons in a two-dimensional electron gas that is formed in the first nitride semiconductor layer increases in the area where the third nitride semiconductor layer is formed. The presence of the third nitride semiconductor layer between the p-type fourth nitride semiconductor region and the second nitride semiconductor layer shortens the distance that the depletion layer extends from the fourth nitride semiconductor layer into the first nitride semiconductor layer, thus making it possible to reduce the forward voltage at which a forward current starts to flow.

It is preferable that a thickness of the second nitride semiconductor layer in a region where the second nitride semiconductor layer is in direct contact with the anode electrode be smaller than a thickness of the second nitride semiconductor layer in a region where the second nitride semiconductor layer is not in direct contact with the anode electrode.

Thinning of the second nitride semiconductor layer in the region where the second nitride semiconductor layer is in direct contact with the anode electrode makes it possible to further reduce the forward voltage at which a forward current starts to flow.

While the third nitride semiconductor layer must not exit in the region where the second nitride semiconductor layer is in direct contact with the anode electrode, the third nitride semiconductor layer may extend to outside of the area where the anode electrode is formed. In the area where the third nitride semiconductor layer extends, the two-dimensional electron gas becomes higher in concentration, so that the forward voltage drop becomes lower.

It is preferable that a front surface of the second nitride semiconductor layer in a region where the second nitride semiconductor layer is in contact with the anode electrode be covered with an AlO film.

In the SBD described above, the front surface of the second nitride semiconductor layer is exposed by etching the third nitride semiconductor layer and the fourth nitride semiconductor layer, and the anode electrode is formed on the exposed surface. In that case, damage may be done to the exposed front surface of the second nitride semiconductor layer to make the anode electrode unable to make Schottky contact with the second nitride semiconductor layer. By etching the third nitride semiconductor layer and the fourth nitride semiconductor layer to expose the front surface of the second nitride semiconductor layer under such conditions that the front surface of the second nitride semiconductor layer is covered with the AlO film, the anode electrode and the second nitride semiconductor layer are as a result brought into stable Schottky contact with each other.

The technology disclosed herein makes it possible to obtain, with use of nitride semiconductors that are superior in property to Si, an SBD which is low in forward voltage drop, which is low in leakage current, which is high in breakdown voltage, and, what is more, which is low in forward voltage at which a forward current starts to flow. The SBD thus obtained is small in loss.

### BRIEF DESCRIPTION OF DRAWINGS

FIG. 1 is a cross-sectional view of a semiconductor device of a first embodiment;

FIG. 2 is a cross-sectional view of a semiconductor device of a second embodiment;

FIG. 3 is a cross-sectional view of a semiconductor device of a third embodiment;

FIG. 4 is a cross-sectional view of a conventional semiconductor device; and

FIG. 5 is a cross-sectional view of another conventional semiconductor device.

### DETAILED DESCRIPTION OF INVENTION

The following organizes the features of the technology disclosed herein. It should be noted that each of the matters described below independently has technical utility.

(First Feature) An SBD and an HEMT (high electron mobility transistor) are formed in one nitride semiconductor substrate.
(Second Feature) A substrate, a buffer layer, a first nitride semiconductor layer, a second nitride semiconductor layer, a third nitride semiconductor layer, and a fourth nitride semiconductor layer are laminated to form the nitride semiconductor substrate.
(Third Feature) In the HEMT, the first nitride semiconductor layer serves as an electron transit layer, and the second nitride semiconductor layer serves as an electron supply layer. The third nitride semiconductor layer and the fourth nitride semiconductor layer are sandwiched between the electron supply layer and a gate electrode, so that the HEMT is normally off.

### First Embodiment

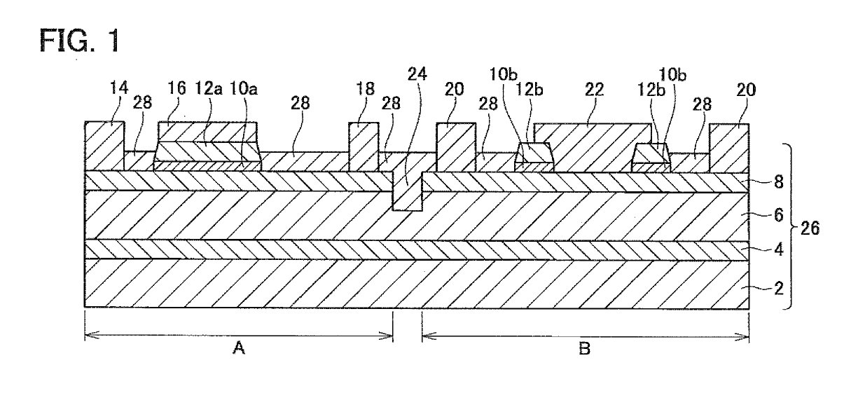

In a semiconductor device of a first embodiment, as shown in FIG. 1, an HEMT and an SBD are formed in one nitride semiconductor substrate 26. The HEMT is formed in an area A, and the SBD is formed in an area B.

The nitride semiconductor substrate 26 of the present embodiment includes a laminated structure of: a substrate 2; a buffer layer 4 formed by crystal growth on a front surface of the substrate 2; a first nitride semiconductor layer 6 formed by crystal growth on a front surface of the buffer layer 4; a second nitride semiconductor layer 8 formed by crystal growth on a front surface of the first nitride semiconductor layer 6; a third nitride semiconductor layer 10 formed by crystal growth on a front surface of the second nitride semiconductor layer 8; and a fourth nitride semiconductor layer 12 formed by crystal growth on a front surface of the third nitride semiconductor layer 10.

When seen in planar view, the nitride semiconductor substrate 26 has some regions from which the third nitride semiconductor layer 10 and the fourth nitride semiconductor layer 12 have been removed. FIG. 1 shows third nitride semiconductor regions 10a and 10b and fourth nitride semiconductor regions 12a and 12b, which remains after the removal. It should be noted that the third nitride semiconductor region 10b and the fourth nitride semiconductor region 12b have a ring shape when the nitride semiconductor substrate 26 is seen in planar view.

The first nitride semiconductor layer 6 is a layer configured to serve as an electron transit layer of the HEMT. The first nitride semiconductor layer 6 is formed by a crystal of a nitride semiconductor. The second nitride semiconductor layer 8 is a layer configured to serve as an electron supply layer of the HEMT. The second nitride semiconductor layer 8 is formed by a crystal of a nitride semiconductor. The first nitride semiconductor layer 6 is narrower in band gap than the second nitride semiconductor layer 8. A two-dimensional electron gas is present in a region of the first nitride semiconductor layer 6 that extends along the hetero-junction interface.

The third nitride semiconductor layer 10 is wider in band gap than the second nitride semiconductor layer 8. The third nitride semiconductor layer 10 cooperates with the second nitride semiconductor layer 8 to induce a two-dimensional electron gas on a region extending along the hetero-junction interface. In positions facing the third nitride semiconductor regions 10a and 10b, there are increases in density of the two-dimensional electron gas on the hetero-junction interface.

The fourth nitride semiconductor layer 12 is formed by a crystal of a p-type nitride semiconductor. As will be described later, the fourth nitride semiconductor region 12a, which is sandwiched between a gate electrode 16 and the second nitride semiconductor layer 8, adjusts the HEMT so that it has normally-off characteristics. As will be described later, the fourth nitride semiconductor region 12b, which remains in a region where an anode electrode 22 and the second nitride semiconductor layer 8 are in Schottky contact with each other, improves the characteristics of the SBD.

An object of the nitride semiconductor substrate 26 is to provide a laminated structure of the first nitride semiconductor layer 6, the second nitride semiconductor layer 8, the third nitride semiconductor layer 10, and the fourth nitride semiconductor layer 12. The buffer layer 4 needs only be a layer configured to serve as a basis on which the first nitride semiconductor layer 6 is formed by crystal growth on the front surface of the buffer layer 4. The buffer layer 4 does not necessarily need to be a nitride semiconductor layer. The substrate 2 needs only be a layer configured to serve as a basis on which the buffer layer 4 is formed by crystal growth on the front surface of the substrate 2. The substrate 2 does not necessarily need to be a nitride semiconductor substrate. In a case where a nitride semiconductor substrate is used as the substrate 2, the buffer layer 4 can be omitted. When the buffer layer 4 is used, a substrate other than a nitride semiconductor substrate, such as a Si substrate or a sapphire substrate, can be used as the substrate 2.

The third nitride semiconductor layer 10 and the fourth nitride semiconductor layer 12 do not necessarily need to be nitride semiconductor layers. However, for crystal growth on the front surface of the second nitride semiconductor layer 8, it is practical to use crystal layers of nitride semiconductors.

As is clear from the above, the term “nitride semiconductor substrate” as used herein refers to a substrate including a laminated structure of the first nitride semiconductor layer 6, the second nitride semiconductor layer 8, the third nitride semiconductor layer 10, and the fourth nitride semiconductor layer 12. The substrate 2 and the buffer layer 4 are not essential.

The present embodiment uses a Si substrate as the substrate 2, an AlGaN layer as the buffer layer 4, an i-type GaN layer as the first nitride semiconductor layer 6, an i-type AlxGa₁₋ₓN layer as the second nitride semiconductor layer 8, an i-type InAlN layer as the third nitride semiconductor layer 10, and a p-type Al_{y}Ga_{1-y}N layer as the fourth nitride semiconductor layer 12. The GaN layer is narrower in band gap than the AlxGa₁₋ₓN layer, and the AlxGa₁₋ₓN layer is narrower in band gap than the InAlN layer. The InAlN layer may be replaced with an AlN layer as the third nitride semiconductor layer 10. The first nitride semiconductor layer 6, the second nitride semiconductor layer 8 and the third nitride semiconductor layer 10 are not a p-type.

In the present embodiment, an element separating groove 24 extending from the front surface of the second nitride semiconductor layer 8 to the first nitride semiconductor layer 6 is formed so that the area A where the HEMT is formed and the area B where the SBD is formed are electrically insulated from each other. The insulation may be achieved by injecting impurity ions instead of forming the groove.

In the area A where the HEMT is formed, as shown in FIG. 1, the third nitride semiconductor layer 10 and the fourth nitride semiconductor layer 12 are removed by etching from areas other than an area where the after-mentioned gate electrode 16 is formed, and the front surface of the second nitride semiconductor layer 8 is exposed. However, the second nitride semiconductor layer 8 contains Al, and the front surface thereof is oxidized. For this reason, the front surface of the second nitride semiconductor layer 8 is covered with an AlO film.

In the area A where the HEMT is formed, a source electrode 14 and a drain electrode 18 are formed on the front surface, which is covered with the AlO film, of the second nitride semiconductor layer 8. The source electrode 14 and the drain electrode 18 are formed by a metal film that makes an Ohmic contact with the front surface of the second nitride semiconductor layer 8. In a position between the source electrode 14 and the drain electrode 18, i.e. a position of separation between the source electrode 14 and the drain electrode 18, the portion 10a of the third nitride semiconductor layer 10 and the portion 12a of the p-type fourth nitride semiconductor layer 12 remain, and the gate electrode 16 is formed on a front surface of the portion 12a.

As described above, the GaN layer, which constitutes the first nitride semiconductor layer 6, is narrower in band gap than the AlₓGa₁₋ₓN layer, which constitutes the second nitride semiconductor layer 8, and a two-dimensional electron gas is formed in an area extending along the hetero-junction interface of the first nitride semiconductor layer 6.

In a position facing the hetero-junction interface, the p-type fourth nitride semiconductor region 12a remains. From the p-type fourth nitride semiconductor region 12a, a depletion layer extends toward the second nitride semiconductor layer 8 and the first nitride semiconductor layer 6. In the absence of a positive potential applied to the gate electrode 16, an area on the hetero-junction interface that faces the gate electrode 16 across the p-type fourth nitride semiconductor region 12a becomes depleted. As a result, electrons cannot move between the source electrode 14 and the drain electrode 18. That is, no electricity flows between the source electrode 14 and the drain electrode 18. In the presence of a positive potential applied to the gate electrode 16, the depletion layer disappears. As a result, the source electrode 14 and the drain electrode 18 are connected to each other through the two-dimensional electron gas. That is, electricity flows between the source electrode 14 and the drain electrode 18. This shows that the HEMT obtained in the area A is of a normally-off type. The first nitride semiconductor layer 6, through which electrons move, is of an i type, and contains few impurities that inhibit the movement of electrons. This HEMT is low in on resistance.

In the area B where the SBD is formed, the anode electrode 22 and a cathode electrode 20 are formed on the front surface, which is covered with the AlO film, of the second nitride semiconductor layer 8.

The anode electrode 22 is formed by a metal film that makes a Schottky contact with the front surface of the second nitride semiconductor layer 8, and the cathode electrode 20 is formed by a metal film that makes an Ohmic contact with the front surface of the second nitride semiconductor layer 8, whereby the SBD is obtained. A forward current flows through a position along the hetero-junction interface of the first nitride semiconductor layer 6. The forward voltage drop is low.

In a portion of the area where the anode electrode 22 is formed, the third nitride semiconductor region 10b and the fourth nitride semiconductor region 12b remain. The p-type fourth nitride semiconductor region 12b, which is present in the portion of the area where the anode electrode 22 is formed, provides a JBS (junction barrier Schottky) structure. That is, in the presence of a backward voltage applied to the SBD, a depletion layer extends from the p-type fourth nitride semiconductor region 12b to the first nitride semiconductor layer 6 through the third nitride semiconductor region 10b and the second nitride semiconductor layer 8 to reduce the leakage current. Further, the concentration of electric fields is relaxed, and a higher breakdown voltage is achieved. Meanwhile, the presence of the third nitride semiconductor region 10b between the fourth nitride semiconductor region 12b and the second nitride semiconductor layer 8 easily induces a two-dimensional electron gas on the hetero-junction interface between the first nitride semiconductor layer 6 and the second nitride semiconductor layer 8, and mere application of a low voltage in the forward direction causes a current to flow between the anode and the cathode. The SBD of FIG. 1 is low in forward voltage drop, small in backward current (leakage current), high in breakdown voltage, and low in forward voltage at which a forward current starts to flow.

In the foregoing, the source electrode 14 of the FET makes contact with the second nitride semiconductor layer 8 via the AlO film. The AlO film is high in resistance, and the presence of the AlO film between the source electrode 14 and the second nitride semiconductor layer 8 raises concern about an increase in on resistance of the HEMT. However, a reduction in thickness of the AlO film can keep the increase in on resistance at a non-problematic level. The same applies to the drain electrode 18. The AlO film can be made thinner to such an extent that there is no increase in resistance between the drain electrode 18 and the second nitride semiconductor layer 8. The same applies to the cathode electrode 20. The AlO film can be made thinner to such an extent that there is no increase in resistance between the cathode electrode 20 and the second nitride semiconductor layer 8, Even when made so thinner, the AlO film allows the anode electrode 22 and the second nitride semiconductor layer 8 to make a Schottky contact with each other.

In the absence of the AlO film covering the front surface of the second nitride semiconductor layer 8, no Schottky contact is made even by forming the anode electrode 22 with use of a material that makes a Schottky contact with the second nitride semiconductor layer 8. Etching damage is done to the front surface of the second nitride semiconductor layer 8 when the front surface of the second nitride semiconductor layer 8 is exposed by etching the third nitride semiconductor layer 10 and the fourth nitride semiconductor layer 12; therefore, the anode electrode 22 does not make a Schottky contact with the second nitride semiconductor layer 8. In the presence of the AlO film covering the front surface of the second nitride semiconductor layer 8, the etching damage no longer exerts influence, so that the anode electrode 22 and the second nitride semiconductor layer 8 make a Schottky contact with each other.

### Second Embodiment

In the following, the same members as those of the first embodiment are given the same reference numbers, and as such, are not described, and only points of difference are described.

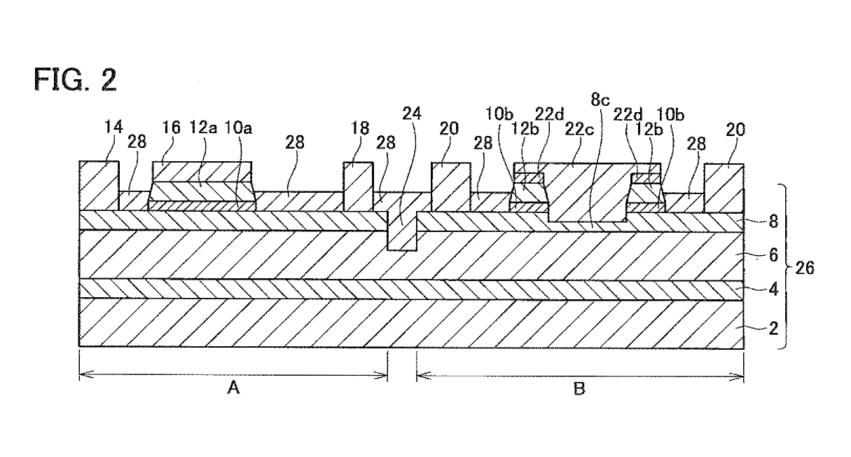

In a semiconductor device of the second embodiment, as shown in FIG. 2, the second nitride semiconductor layer 8 is made thinner in an area where it is in direct contact with an anode electrode 22c. When the anode electrode 22c faces the hetero-junction interface across the thinner second nitride semiconductor layer 8c, a voltage drop that occurs in a case where a forward current flows is kept down. Further, a forward voltage at which a forward current starts to flow becomes low.

Removal of the third nitride semiconductor region 10b from the structure of FIG. 1 causes no forward current to flow unless the forward voltage is 1.2 volts or higher. On the other hand, the addition of the third nitride semiconductor region 10b and the thinning of the second nitride semiconductor layer 8 brought about such improved characteristics that a forward current flows when the forward voltage is 0.5 volts or higher.

In a case where the thinner second nitride semiconductor layer 8c is formed by making a portion of the second nitride semiconductor layer 8 thinner by etching, it is preferable that the etching be performed under such conditions that an AlO film is formed on a front surface of the thinner second nitride semiconductor layer 8c. This allows the thinner second nitride semiconductor layer 8c and the anode electrode 22c to be in such a relationship as to make stable Schottky contact with each other.

Further, in the second embodiment, an electrode 22d configured to make Ohmic contact with the fourth nitride semiconductor region 12b is formed on a front surface of the fourth nitride semiconductor region 12b. The addition of the electrode 22d stabilizes a potential of the fourth nitride semiconductor region 12b, thereby stabilizing the behavior of a depletion layer extending from the fourth nitride semiconductor region 12b. This allows stabilization of the characteristics of an SBD which is low in forward voltage drop, which is low in leakage current, which is high in breakdown voltage, and which is low in forward voltage at which a forward current starts to flow.

### Third Embodiment

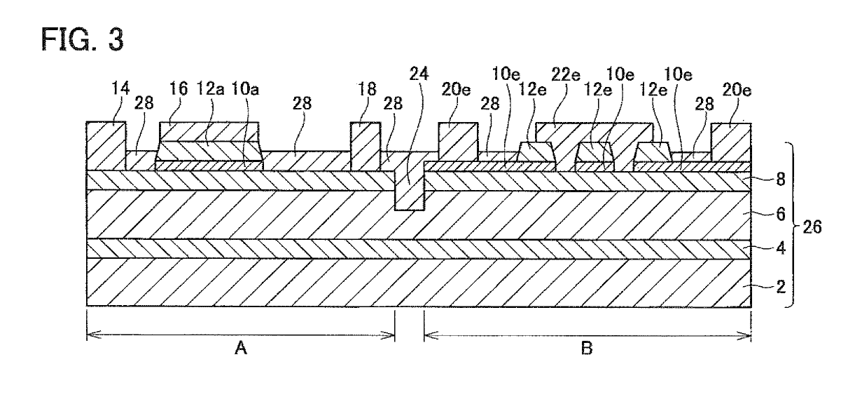

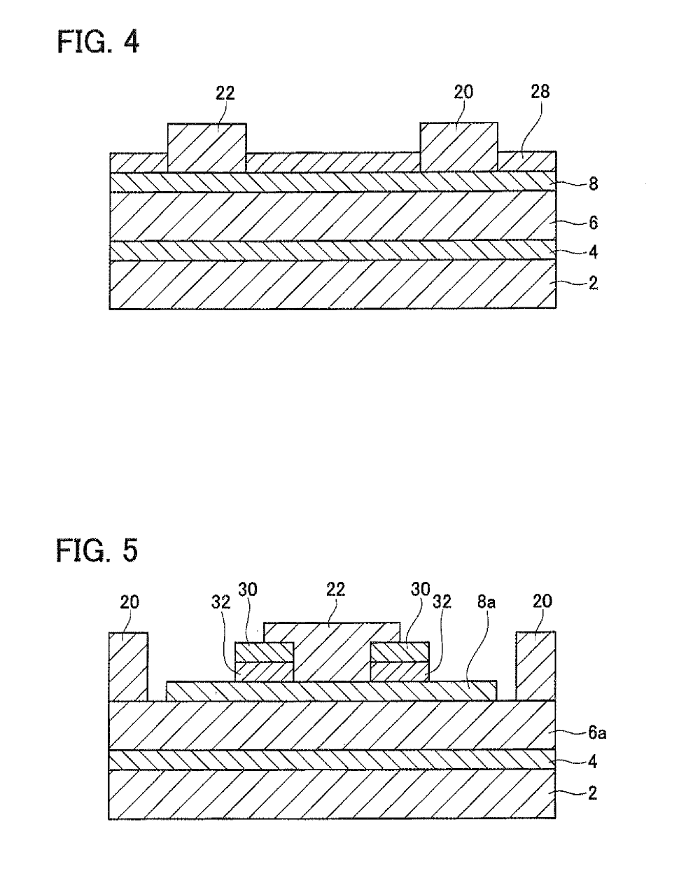

As shown in FIG. 3, a shape of a fourth nitride semiconductor region 12e is not limited to a ring shape. It is only necessary that a plurality of fourth nitride semiconductor regions 12e be dispersedly formed in an area where an anode electrode 22e is formed. The leakage current, the breakdown voltage, and the like can be adjusted by adjusting the interval between fourth nitride semiconductor regions 12e.

Further, as shown in FIG. 3, a third nitride semiconductor region 10e may be removed in a region where the anode electrode 22e and the second nitride semiconductor layer 8 are in direct contact with each other, and may remain in other regions. A remaining portion of the third nitride semiconductor region 10 in a position between the anode electrode 22e and a cathode electrode 20e increases the density of a two-dimensional electron gas on a hetero-junction interface located between the anode electrode 22e and the cathode electrode 20e, so that the forward voltage drop is further kept down.

While specific examples of the present invention have been described above in detail, these examples are merely illustrative and place no limitation on the scope of the patent claims. The technology described in the patent claims also encompasses various changes and modifications to the specific examples described above.

The technical elements explained in the present description or drawings provide technical utility either independently or through various combinations. The present invention is not limited to the combinations described at the time the claims are filed. Further, the purpose of the examples illustrated by the present description or drawings is to satisfy multiple objectives simultaneously, and satisfying any one of those objectives gives technical utility to the present invention.

### REFERENCE SINGS LIST

2: Substrate
4: Buffer layer
6: i-type GaN layer (embodiment of a first nitride semiconductor layer)
8: i-type AlGaN layer (embodiment of a second nitride semiconductor layer)
10: i-type InAlN layer (embodiment of a third nitride semiconductor layer)
12: p-type AlGaN layer (embodiment of a fourth nitride semiconductor layer)
14: Source electrode
16: Gate electrode
18: Drain electrode
20: Cathode electrode
22: Anode electrode
24: Element separating region
26: Substrate of laminated s nitride semiconductors
28: Passivation film
30: SiO₂ film
32: p-type GaN region

What is claimed is:

1. An SBD in which an anode electrode and a cathode electrode are formed on a front surface of a nitride semiconductor substrate,
the nitride semiconductor substrate comprising a laminated structure in which a first nitride semiconductor layer, a second nitride semiconductor layer, a third nitride semiconductor layer, and a fourth nitride semiconductor layer are laminated in this order from a back surface side of the nitride semiconductor substrate to a front surface side of the nitride semiconductor substrate,
wherein
when seen in planar view, the nitride semiconductor substrate has some regions from which the third nitride semiconductor layer and the fourth nitride semiconductor layer have been removed, and in a cross-sectional view of an area where the anode electrode is formed, there is a mixture of a region where there is a laminated structure of the first nitride semiconductor layer, the second nitride semiconductor layer, the third nitride semiconductor layer, the fourth nitride semiconductor layer, and the anode electrode and a region where there is a laminated structure of the first nitride semiconductor layer, the second nitride semiconductor layer, and the anode electrode,
the first nitride semiconductor layer is narrower in band gap than the second nitride semiconductor layer, and the second nitride semiconductor layer is narrower in band gap than the third nitride semiconductor layer,
a conductivity type of each of the first nitride semiconductor layer, the second nitride semiconductor layer, and the third nitride semiconductor layer is not a p type, and
a conductivity type of the fourth nitride semiconductor layer is a p type.

2. The SBD as set forth in claim 1, wherein a thickness of the second nitride semiconductor layer in a region where the second nitride semiconductor layer is in contact with the anode electrode is smaller than a thickness of the second nitride semiconductor layer in a region where the second nitride semiconductor layer is not in contact with the anode electrode.

3. The SBD as set forth in claim 1, wherein the third nitride semiconductor layer extends to outside of the area where the anode electrode is formed.

4. The SBD as set forth in claim 2, wherein the third nitride semiconductor layer extends to outside of the area where the anode electrode is formed.

5. The SBD as set forth in claim 1, wherein a front surface of the second nitride semiconductor layer in a region where the second nitride semiconductor layer is in contact with the anode electrode is covered with an AlO film.

6. The SBD as set forth in claim 2, wherein a front surface of the second nitride semiconductor layer in a region where the second nitride semiconductor layer is in contact with the anode electrode is covered with an AlO film.

7. The SBD as set forth in claim 3, wherein a front surface of the second nitride semiconductor layer in a region where the second nitride semiconductor layer is in contact with the anode electrode is covered with an AlO film.

8. The SBD as set forth in claim 4, wherein a front surface of the second nitride semiconductor layer in a region where the second nitride semiconductor layer is in contact with the anode electrode is covered with an AlO film.
